(19) United States
(12) Patent Application Publication
(10) Pub. No.: US 2026/0291058 A1
(43) Pub. Date: Sep. 24, 2026

(54) ELECTRONIC DEVICE

(71) Applicant: DONGWOO FINE-CHEM CO., LTD., Jeonbuk-do (KR)

(72) Inventors: YOON HO HUH, Jeonbuk-do (KR); JONG SU LEE, Jeonbuk-do (KR); DO HYOUNG KWON, Jeonbuk-do (KR); WON HEE LEE, Jeonbuk-do (KR); SUNG JOON HONG, Jeonbuk-do (KR)

(21) Appl. No.: 19/569,883

(22) Filed: Mar. 17, 2026

(30) Foreign Application Priority Data
Mar. 18, 2025 (KR) 10-2025-0034559

(51) Int. Cl. H01Q 1/27; H01Q 9/04

(52) U.S. Cl. CPC H01Q 1/273; H01Q 9/0414

(57) ABSTRACT

An electronic device includes a display panel, an antenna element stacked on the display panel, a rear board disposed under the display panel, an antenna circuit board including one end portion connected to the antenna element, the other end portion connected to the rear board, and a vertical extension portion between the one end portion and the other end portion, and a forming structure disposed on the other end portion of the antenna circuit board to be adjacent to an inner surface of the vertical extension portion.

### CROSS-REFERENCE TO RELATED APPLICATION AND CLAIM OF PRIORITY

This application claims priority to Korean Patent Application No. 10-2025-0034559 filed on Mar. 18, 2025 in the Korean Intellectual Property Office (KIPO), the entire disclosures of which are incorporated by reference herein.

### BACKGROUND

### 1. Technical Field

The present invention relates to an electronic device. More specifically, the present invention relates to an electronic device including an antenna element.

### 2. Description of the Related Art

As information technologies have been developed, a wireless communication technology such as Wi-Fi, Bluetooth, etc., is combined or embedded in an image display device, an electronic device, an architecture, etc. In this case, an antenna may be combined with the image display device to provide a communication function. As mobile communication technologies have been rapidly developed, an antenna for performing high-frequency or ultrahigh-frequency communication is being applied to public transportation such as a bus and a subway, a building structure, various mobile devices, wearable devices, and the like.

When the antenna is applied to an electronic device such as an image display device, mutual interference may occur between a conductor such as an electrode or a wiring included in the electronic device, and the antenna. For example, when the antenna is connected to an integrated circuit chip in the electronic device, additional signal interference and signal loss may occur.

Additionally, if the antenna covers a display area of the image display device or the antenna is visually recognized by a user, image properties of the image display device can be deteriorated.

Thus, construction of the antenna that may suppress disturbance with electrical/optical properties in image display devices while maintaining or enhancing radiation properties of the antenna may be needed.

### SUMMARY

According to an aspect of the present invention, there is provided an electronic device providing improved radiation and electrical properties.

(1) An electronic device, including: a display panel; an antenna element stacked on the display panel; a rear board disposed under the display panel; an antenna circuit board including one end portion connected to the antenna element, the other end portion connected to the rear board, and a vertical extension portion between the one end portion and the other end portion; and a forming structure disposed on the other end portion of the antenna circuit board to be adjacent to an inner surface of the vertical extension portion.

(2) The electronic device of the above (1), wherein the forming structure includes an elastic resin material.

(3) The electronic device of the above (2), further including an auxiliary forming structure disposed on the other end portion of the antenna circuit board.

(4) The electronic device of the above (3), wherein the auxiliary forming structure is spaced apart from the vertical extension portion of the antenna circuit board with the forming structure interposed therebetween.

(5) The electronic device of the above (3), wherein the auxiliary forming structure is a sensor element including a conductor.

(6) The electronic device of the above (1), wherein the antenna circuit board has a first bent portion formed between the one end portion and the vertical extension portion, and a second bent portion formed between the other end portion and the vertical extension portion.

(7) The electronic device of the above (6), wherein a bent angle of each of the first bent portion and the second bent portion is within a range of 80° to 100°.

(8) The electronic device of the above (6), wherein the first bent portion and the second bent portion do not include a curved surface.

(9) The electronic device of the above (6), wherein the one end portion of the antenna circuit board includes a first horizontal extension portion, and the other end portion of the antenna circuit board includes a second horizontal extension portion.

(10) The electronic device of the above (6), wherein the antenna circuit board has a third bent portion under the display panel and a fourth bent portion adjacent to the forming structure, and the vertical extension portion includes a first vertical extension portion between the first bent portion and the second bent portion, and a second vertical extension portion between the third bent portion and the fourth bent portion.

(11) The electronic device of the above (1), wherein the forming structure contacts an inner surface of the vertical extension portion of the antenna circuit board.

(12) The electronic device of the above (1), further including: a first antenna connection structure mounted on the other end portion of the antenna circuit board; and a second antenna connection structure mounted on the rear board and coupled to the first antenna connection structure.

(13) The electronic device of the above (12), wherein the forming structure is disposed on an inner surface of the other end portion of the antenna circuit board, and the first antenna connection structure is mounted on an outer surface opposing the inner surface of the other end portion of the antenna circuit board.

(14) The electronic device of the above (12), wherein the first antenna connection structure and the second antenna connection structure include a connector, a pogo pin, or a c-clip.

(15) The electronic device of the above (1), wherein the antenna element includes: an antenna dielectric layer having a curved circumference; and a radiator electrically connected to the antenna circuit board, the radiator extending along the curved circumference of the antenna dielectric layer and having a curved shape.

(16) The electronic device of the above (15), wherein the radiator includes a mesh portion.

(17) The electronic device of the above (16), wherein the radiator further includes a solid portion.

(18) The electronic device of the above (17), wherein the solid portion and the mesh portion are integrally connected and have the same curvature.

(19) The electronic device of the above (1), the electronic device is provided as a smartwatch.

In an electronic device according to example embodiments, an antenna element may be connected to a rear board of the electronic device through a circuit board having a plurality of substantially vertical bent portions. Accordingly, signal efficiency and ground efficiency through the circuit board may be improved, and spatial efficiency of the electronic device may be improved.

The antenna element may include a curved radiator extending along a curved circumference on a top surface of a dielectric layer having the curved circumference. Accordingly, antenna radiation properties may be achieved while avoiding interference with electrical/optical properties of the electronic device to which the antenna element is applied.

The antenna element may be applied to an electronic device such as an image display device having a curved perimeter or a wearable device such as a smart watch to effectively implement an electronic device that provides high-frequency or ultrahigh-frequency communication.

### BRIEF DESCRIPTION OF THE DRAWINGS

FIG. 1 is a schematic perspective view illustrating an electronic device according to embodiments.

FIG. 2 is a schematic cross-sectional view illustrating an electronic device according to embodiments.

FIG. 3 is a schematic plan view illustrating a display panel according to embodiments.

FIG. 4 is a schematic plan view illustrating an antenna element according to embodiments.

FIG. 5 is a schematic plan view illustrating an antenna device according to embodiments.

FIG. 6 is a schematic cross-sectional view illustrating an antenna device according to embodiments.

FIG. 7 is a schematic cross-sectional view illustrating an electronic device according to embodiments.

FIG. 8 is a schematic cross-sectional view illustrating an electronic device according to embodiments.

FIG. 9 is a schematic cross-sectional view illustrating an electronic device according to Comparative Example.

FIG. 10 is a graph illustrating a gain with frequency of antenna devices according to Example and Comparative Example.

### DETAILED DESCRIPTION OF THE EMBODIMENTS

Embodiments of the present invention provide an electronic device including an antenna element and a circuit board.

Hereinafter, the present invention will be described in detail with reference to the accompanying drawings. However, those skilled in the art will appreciate that such embodiments described with reference to the accompanying drawings are provided to further understand the spirit of the present invention and do not limit subject matters to be protected as disclosed in the detailed description and appended claims.

The terms “first,” “second,” “third,” “one end,” “the other end,” “upper side,” “lower side,” “lateral side”, etc., herein are used to relatively distinguish positions of components, and are not intended to designate absolute positions.

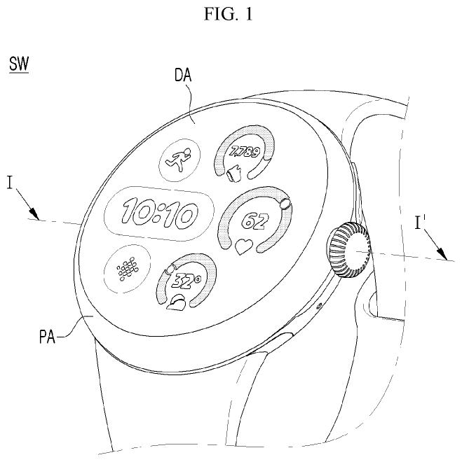

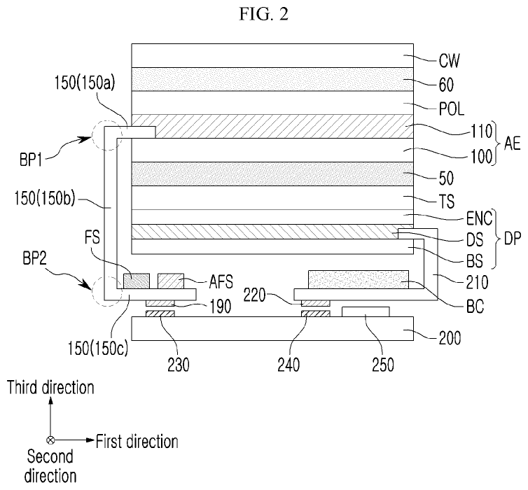

FIG. 1 is a schematic perspective view illustrating an electronic device according to embodiments. FIG. 2 is a schematic cross-sectional view illustrating an electronic device according to embodiments. For example, FIG. 2 is a cross-sectional view taken along line a I-I′ of FIG. 1 in a thickness direction.

In example embodiments, the electronic device may include a display device. In some embodiments, the electronic device may include a wearable device including a display device. In an embodiment, the electronic device may include a smart watch SW as illustrated in FIG. 1.

A first direction and a second direction may refer to two directions parallel to a display surface of the electronic device and perpendicular to each other. For example, the first direction may correspond to an X direction (a row direction) of the electronic device, and the second direction may correspond to a Y direction (a column direction) of the electronic device. The third direction may be perpendicular to the first direction and the second direction. The third direction may correspond to a Z direction (a thickness direction) of the electronic device.

The above-described definition of the direction may be equally applied to the accompanying drawings.

Referring to FIG. 1, the electronic device implemented in the form of, e.g., a smart watch SW may include a circular body, and the circular body may include a display area DA and a peripheral area PA. The peripheral area PA may be substantially a bezel area of the circular body.

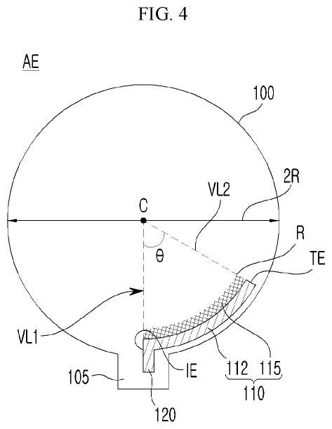

A radiator 110 of an antenna element AE (see FIG. 4) may extend along the peripheral area PA. In some embodiments, the radiator 110 may have a mesh structure. In an embodiment, the radiator 110 may further include a solid metal layer.

In some embodiments, as described with reference to FIG. 4, the radiator 110 may include a solid portion 112 and a mesh portion 115. In example embodiments, the solid portion 112 of the radiator 110 may be disposed in the peripheral area PA, and the mesh portion 115 of the radiator 110 may be disposed in the display area DA.

In an embodiment, a boundary between the mesh portion 115 and the solid portion 112 may substantially coincide with the boundary between the display area DA and the peripheral area PA.

In an embodiment, a portion of the mesh portion 115 may be disposed in the peripheral area PA. In an embodiment, a portion of the solid portion 112 may be disposed in the display area DA.

As described above, the solid portion 112 and the mesh portion 115 may be included in the radiator 110 together to suppress electrical interference with a display panel DP and/or a touch sensor layer TS, and desired radiation properties may be implemented. Further, deterioration of an image quality implemented from the display panel DP by the radiator 110 may be prevented.

Referring to FIG. 2, the electronic device may include the display panel DP and the antenna element AE stacked on the display panel DP. The electronic device may further include a cover window CW disposed on the antenna element to provide a display screen or an outermost surface of FIG. 1.

The display panel DP may include a base substrate BS, a display structure DS disposed on the base substrate BS, and an encapsulation layer ENC covering the display structure DS.

The base substrate BS may be provided as a support substrate or a back-plane substrate of the electronic device. A glass substrate or a plastic substrate may be used as the base substrate BS.

In some embodiments, the base substrate BS may include a polymer material having transparency and flexibility. In this case, the display substrate may be used in a transparent flexible display device. For example, the base substrate BS may include a polymer material such as polyimide, polysiloxane, an epoxy resin, an acrylic resin, polyester, or the like. In an embodiment, the base substrate BS may include polyimide.

The display structure DS may include, e.g., a thin film transistor (TFT) array. The display structure DS may be disposed on the TFT array, and may include a display element including a stack of an anode, a display layer and a cathode. For example, the display layer may include an organic emission layer, and the display element may be an organic light-emitting diode (OLED) element.

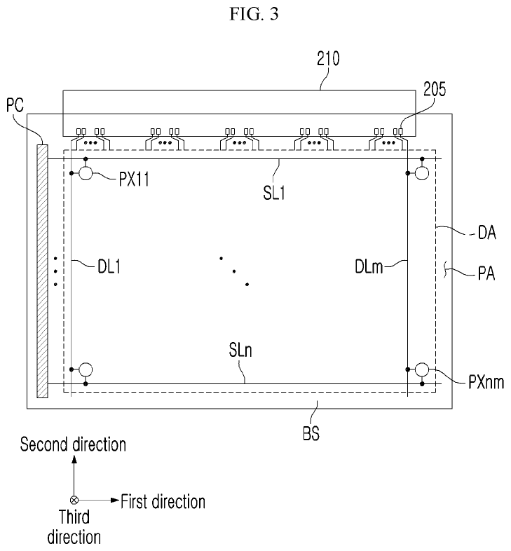

Structures and elements of the display structure DS will be described in more detail with reference to FIG. 3.

The antenna element AE may be disposed on the display panel DP. In some embodiments, the touch sensor layer TS may be disposed between the antenna element AE and the display panel DP. As will be described later with reference to FIG. 4, the antenna element AE may include an antenna dielectric layer 100 and a radiator 110 (including a pad portion 120).

In an embodiment, the touch sensor layer TS may include a sensor substrate layer and sensing electrodes arranged on the sensor substrate layer. In an embodiment, the touch sensor layer TS may be included as an on-cell type sensor including sensing electrodes directly formed on the display panel DP.

A first adhesive layer 50 may be formed between the antenna element AE and the display panel DP. For example, the first adhesive layer 50 may be formed between the antenna element AE and the touch sensor layer TS.

In some embodiments, a polarizing layer POL may be stacked on the antenna element AE. The polarizing layer POL may include a coated polarizer or a polarizing plate. The coated polarizer may include a liquid crystal coating layer including a polymerizable liquid crystal compound and a dichroic dye. In this case, the polarizing layer POL may further include an alignment layer for providing an orientation to the liquid crystal coating layer

For example, the polarizing plate may include a polyvinyl alcohol-based polarizer and a protective film attached to at least one surface of the polyvinyl alcohol-based polarizer.

The cover window CW may include, e.g., glass or a transparent resin film. In some embodiments, a light-shielding pattern may be formed on a peripheral portion of one surface of the cover window CW. The light-shielding pattern may include, e.g., a color printing pattern, and may have a single-layered or a multi-layered structure. The peripheral area PA or the bezel area may be defined by the light-shielding pattern.

For example, a second adhesive layer 60 may be formed between the polarizing layer POL and the cover window CW. In some embodiments, an adhesive layer may be formed between the antenna element AE and the polarizing layer POL.

The electronic device may further include a rear board 200 disposed under the display panel DP. In example embodiments, the rear board 200 may be a main board in the form of a rigid circuit board. A second antenna connection structure 230 may be mounted on the rear board 200. A circuit element 250 and a second display connector 240 may be further mounted on the rear board 200.

For example, the circuit element 250 may include a display driving integrated circuit chip for driving the TFT array or the display structure DS, a touch sensor driving integrated circuit chip, an antenna driving integrated circuit chip, an AP (application) processor, or the like.

The antenna element AE may be electrically connected to the antenna driving integrated circuit chip through an antenna circuit board 150. Accordingly, feeding and signal transfer from the antenna driving integrated circuit chip to the radiator 110 may be performed.

One end portion of the antenna circuit board 150 may be coupled to the pad portion 120 of the antenna element AE. The antenna circuit board 150 may be bent downward with respect to the antenna element AE, so that the first antenna connection structure 190 mounted on the other end portion of the antenna circuit board 150 and the second antenna connection structure 230 mounted on the rear board 200 may be coupled to each other.

Accordingly, an electrical connection structure of the antenna driving integrated circuit chip-antenna circuit board 150—the antenna element AE may be implemented.

Each of the first antenna connection structure 190 and the second antenna connection structure 230 may include a connector, a pogo pin, a c-clip, or the like.

In an embodiment, the first antenna connection structure 190 may be a first connector, and the second connection structure 230 may be a second connector coupled to the first connector.

In an embodiment, the first antenna connection structure 190 may be a pogo pin, and the second antenna connection structure 230 may be a pin pad in contact with or connected to the pogo pin.

In example embodiments, the antenna circuit board 150 may include a first bent portion BP1 and a second bent portion BP2. The antenna circuit board 150 may extend in a substantially vertical direction by the first bent portion BP1.

The antenna circuit board 150 may extend again in a horizontal direction (for example, in the first direction) by the second bent portion BP2. Accordingly, the other end portion of the antenna circuit board 150 may be positioned between the display panel DP and the rear board 200.

According to embodiments of the present invention, the antenna circuit board 150 may not substantially include a curved bent portion. As described above, each of the first and second bent portions BP1 and BP2 may be a vertical bent portion that does not include a curved surface.

In example embodiments, a bending angle of the antenna circuit board 150 by the first bent portion BP1 and the second bent portion BP2 may substantially maintain a range from 80° to 100°, a range from 85° to 95°, or substantially 90°.

The antenna circuit board 150 may include a first horizontal extension portion 150a, a vertical extension portion 150b and a second horizontal extension portion 150c by the first and second bent portion BP1 and BP2.

The first horizontal extension portion 150a and the second horizontal extension portion 150c may extend substantially parallel to a top surface of the electronic device or the display panel DP. The vertical extension portion 150b may extend substantially parallel to a side surface of the electronic device.

The first horizontal extension portion 150a may be bonded or electrically connected to the antenna element AE. The first antenna connection structure 190 may be mounted on the second horizontal extension portion 150c to be coupled to the second antenna connection structure 230.

In example embodiments, a forming structure FS may be disposed on the second horizontal extension portion 150c. For example, the forming structure FS may be disposed on an inner surface of the second horizontal extension portion 150c, and the first antenna connection structure 190 may be mounted on an outer surface of the second horizontal extension portion 150c.

The forming structure FS may be an insulating pattern. In some embodiments, the forming structure FS may include a resin material having an elasticity. For example, the forming structure FS may include an acrylic resin, a urethane resin, a silicone resin, a polyester resin, an epoxy resin, etc.

The forming structure FS may be provided as a support for stably maintaining the bent shape of the antenna circuit board 150 as described above. For example, the forming structure FS may be positioned on the other end portion of the antenna circuit board 150 or the second horizontal extension portion 150c, and the vertical extension portion 150b may be formed by bending the antenna circuit board 150 using the forming structure FS. Thereafter, the one end portion of the antenna circuit board 150 may be bent using a connection support layer 105 of the antenna dielectric layer 100 described later to form the first horizontal extension portion 150a.

As described above, a signal path in a substantially vertical direction may be implemented in a state that the antenna circuit board 150 is adjacent to a side surface of the electronic device using the first and second bent portions BP1 and BP2. Thus, a signal loss and a decrease in ground efficiency caused by the curved signal path may be prevented, and antenna radiation properties may be improved.

Further, a lateral space occupied by the antenna circuit board 150 may be reduced, and the antenna circuit board 150 may be stably accommodated in the peripheral area PA of the electronic device.

In some embodiments, an auxiliary forming structure AFS may be further disposed on the second horizontal extension portion 150c of the antenna circuit board 150. The auxiliary forming structure AFS may be spaced apart from the vertical extension portion 150b of the antenna circuit board 150 with the forming structure FS interposed therebetween. In some embodiments, the forming structure FS may be closer to an inner surface (an inner sidewall) of the vertical extension portion 150b than the auxiliary forming structure AFS, but may be spaced apart from the inner surface of the vertical extension portion 150b.

The auxiliary forming structure AFS may include a conductor. In some embodiments, the auxiliary forming structure AFS may overlap the first and second antenna connection structures 190 and 230 in the third direction or the thickness direction.

Accordingly, the auxiliary forming structure AFS may serve as a ground with respect to noises around the first and second antenna connection structures 190 and 230 while maintaining the curved shape of the antenna circuit board 150 together with the forming structure FS.

In some embodiments, the auxiliary forming structure AFS may include a sensor element such as a heptic sensor, an input sensor, or the like.

The forming structure FS and the auxiliary forming structure AFS may be disposed under the base substrate BS of the display panel DP, and may face the rear board 200 with the second horizontal extension portion 150c of the antenna circuit board 150 interposed therebetween.

One end portion of the display circuit board 210 may be bonded or electrically connected to pads 205 (see FIG. 3) of the display structure DS, and may be bent downward so that the first display connector 220 mounted on the other end portion of the display circuit board 210 may be coupled to the second display connector 240 mounted on the rear board 200.

The second display connector 240 may be electrically connected to the circuit element 250 through a wiring included in the rear board 200.

In some embodiments, a battery BC may be disposed on the other end portion of the display circuit board 210. The battery BC may be used as a forming structure of the display circuit board 210. Accordingly, a bending shape of the display circuit board 210 may have a vertical bending shape substantially the same as or similar to that of the antenna circuit board 150.

FIG. 3 is a schematic plan view illustrating a display panel according to embodiments.

Referring to FIG. 3, a plurality of pixels PX11 to PXnm forming the display structure DS may be arranged in the display area DA of the electronic device or the display panel DP.

In example embodiments, a pixel circuit including scan lines (or gate lines SL1 to SLn) forming first to n^{th} rows and data lines DL1 to DLm forming first to m^{th} columns may be arranged on the base substrate BS of the display panel DP. Each of the pixels PX11 to PXnm may be connected to a scan line of a corresponding row among a plurality of the scan lines SL1 to SLn and a data line of a corresponding column among a plurality of data lines DL1 to DLm.

Each of the display structure DS or the pixels PX11 to PXnm may further include a pixel driving circuit including a transistor and a light-emitting element. Although not illustrated in detail in FIG. 3, the pixel circuit may further include wirings such as a power line, a ground line, or the like.

In FIG. 3, the data lines DL1 to DLm extend in the second direction, and the scan lines SL1 to SLn extend in the first direction, but the arrangement of the scan lines and the data lines is not limited thereto.

A peripheral circuit PC may be disposed in the peripheral area PA corresponding to a non-display area. For example, the peripheral circuit PC may include a gate driving circuit. The gate driving circuit may be integrated into the display panel DP device through an oxide silicon gate (OSG) driver circuit, an amorphous silicon gate (ASG) driver circuit, or a polysilicon gate (PSG) driver circuit process.

The peripheral circuit PC may further include a data driver, a gate driver, a light-emitting driver, a power voltage generator, a timing controller, or the like.

The pads 205 of the pixel circuit may be arranged on one side of the peripheral area PA. The display circuit board 210 may be electrically connected to the pixel circuit through the pads 205. For example, the display circuit board 210 may be electrically connected to the pads 205 by a heat-compression process using a conductive intermediate structure such as an anisotropic conductive film (ACF).

Although the base substrate BS is shown in a square shape in FIG. 3 for convenience of illustration, the base substrate BS may also have a circular shape based on an external shape of the smart watch SW as illustrated in FIG. 1.

FIG. 4 is a schematic plan view illustrating an antenna element according to embodiments.

Referring to FIG. 4, an antenna element AE may include an antenna dielectric layer 100 and a radiator 110 disposed on the antenna dielectric layer 100 and having a curved shape.

In some embodiments, the antenna dielectric layer 100 may include a transparent resin material. For example, the antenna dielectric layer 100 may include a polyester-based resin such as polyethylene terephthalate, polyethylene isophthalate, polyethylene naphthalate and polybutylene terephthalate; a cellulose-based resin such as diacetyl cellulose and triacetyl cellulose; a polycarbonate-based resin; an acrylic resin such as polymethyl (meth)acrylate and polyethyl (meth)acrylate; a styrene-based resin such as polystyrene and an acrylonitrile-styrene copolymer; a polyolefin-based resin such as polyethylene, polypropylene, a cycloolefin or polyolefin having a norbornene structure and an ethylene-propylene copolymer; a vinyl chloride-based resin; an amide-based resin such as nylon and an aromatic polyamide; an imide-based resin; a polyethersulfone-based resin; a sulfone-based resin; a polyether ether ketone-based resin; a polyphenylene sulfide resin; a vinyl alcohol-based resin; a vinylidene chloride-based resin; a vinyl butyral-based resin; an allylate-based resin; a polyoxymethylene-based resin; an epoxy-based resin; a urethane or acrylic urethane-based resin; a silicone-based resin, etc. These may be used alone or in a combination of two or more therefrom.

In an embodiment, the antenna dielectric layer 100 may include a cyclic olefin polymer (COP)-based material.

In some embodiments, an adhesive film such as an optically clear adhesive (OCA) or an optically clear resin (OCR) may be included in the antenna dielectric layer 100.

In some embodiments, the antenna dielectric layer 100 may include an inorganic insulating material such as silicon oxide, silicon nitride, silicon oxynitride, glass, etc.

In an embodiment, the antenna dielectric layer 100 may be provided as a substantially single layer.

In an embodiment, the antenna dielectric layer 100 may include a multi-layered structure of at least two or more layers. For example, the antenna dielectric layer 100 may include a substrate layer and an antenna dielectric layer, and may include an adhesive layer between the substrate layer and the antenna dielectric layer.

An impedance or an inductance of the antenna unit may be formed by the antenna dielectric layer 100 so that a frequency band in which the antenna structure may be driven or operated may be adjusted. In some embodiments, a dielectric constant of the antenna dielectric layer 100 may be adjusted in a range from about 1.5 to about 12. When the dielectric constant is greater than about 12, a driving frequency may be excessively reduced and driving in a high frequency band may not be implemented.

In some embodiments, the connection support layer 105 may be connected to the antenna dielectric layer 100. The connection support layer 105 may be provided as a dielectric layer supporting electrical bonding or adhesion of the antenna circuit board 150 and the pad portion 120. As described above, the connection support layer 105 may maintain or support the shape and the position of the first bent portion BP1 or the first horizontal extension portion 150a of the antenna circuit board 150.

The connection support layer 105 may have a bar shape protruding from the antenna dielectric layer 100. The connection support layer 105 may include substantially the same material as that of the antenna dielectric layer 100, and may be formed of a single member substantially integral with the antenna dielectric layer 100.

According to embodiments of the present invention, the antenna dielectric layer 100 may have a curved circumference. In some embodiments, the antenna dielectric layer 100 may have a substantially circular or elliptical shape.

The radiator 110 may have a curved shape extending along the curved circumference of the antenna dielectric layer 100. In example embodiments, the radiator 110 may extend in the curved shape along the curved circumference of the antenna dielectric layer 100 from a specific point of the circumference of the antenna dielectric layer 100.

In example embodiments, the curved circumferences of the radiator 110 and the antenna dielectric layer 100 may have substantially the same curvature.

The radiator 110 may include silver (Ag), gold (Au), copper (Cu), aluminum (Al), platinum (Pt), palladium (Pd), chromium (Cr), titanium (Ti), tungsten (W), niobium (Nb), tantalum (Ta), vanadium (V), iron (Fe), manganese (Mn), cobalt (Co), nickel (Ni), zinc (Zn), tin (Sn), molybdenum (Mo), calcium (Ca), or an alloy containing at least one thereof. These may be used alone or in a combination of two or more therefrom.

In an embodiment, the radiator 110 may include silver (Ag) or a silver alloy (e.g., a silver-palladium-copper (APC) alloy), or copper (Cu) or a copper alloy (e.g., a copper-calcium (CuCa) alloy) for low resistance implementation and fine line width patterning.

In some embodiments, the radiator 110 may substantially consist of the above-described metal or alloy.

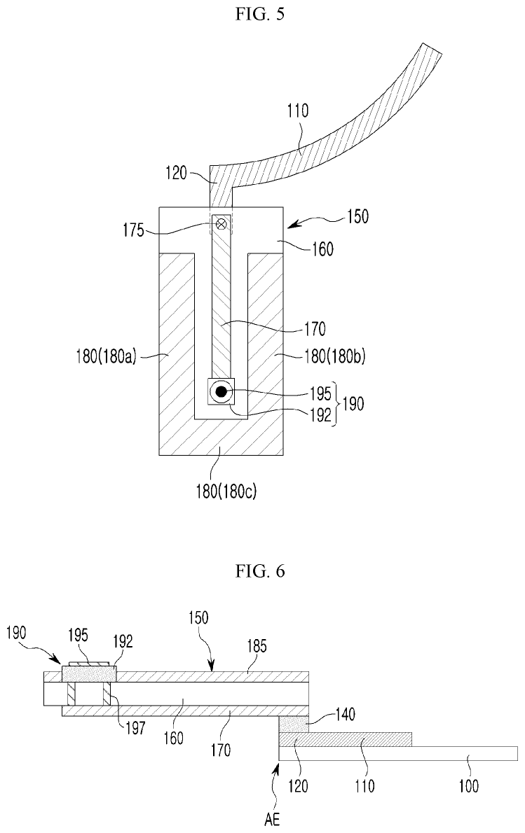

The antenna device may further include the pad portion 120 connected to the radiator 110. The pad portion 120 may be disposed on the connection support layer 105 to be electrically connected to a signal wiring 170 (see FIG. 5) included in the circuit board 150.

The radiator 110 may have a shape bent from the pad portion 120, and may extend clockwise or counterclockwise from the pad portion 120. The pad portion 120 may include substantially the same material as that of the radiator 110, and may be formed as a single member substantially integral with the radiator 110.

In example embodiments, one lateral side of the pad portion 120 and one lateral side of the radiator 110 may substantially coincide with each other. For example, one lateral side of the pad portion 120 and one lateral side of one end portion IE of the radiator 110 may be integrally connected to form the same straight line.

One end portion IE of the radiator 110 may be an initiating end portion extending from the pad portion 120.

In some embodiments, a first virtual straight line VL1 extending from one lateral side of the pad portion 120 and one lateral side of one end portion IE of the radiator 110 may pass through a center C of a top surface of the antenna dielectric layer 100. The center C may be a center of a circle or a center of an ellipse. In an embodiment, the center C may be the center of the circle.

In some embodiments, a second virtual straight line VL2 extending from a lateral side of the other end portion TE of the radiator 110 may pass through the center C of the top surface of the antenna dielectric layer 100.

The first virtual straight line VL1 and the second virtual straight line VL2 may form an intersection angle θ at the center C of the top surface of the antenna dielectric layer 100.

In some embodiments, a length of the curved circumference of the antenna dielectric layer 100 may be calculated as 2πR. As indicated in FIG. 4, R may correspond to a radius of the curved circumference, and 2R may correspond to a diameter of the curved circumference.

In some embodiments, the radiator 110 has a shape of an arc of a circular sector, and the length of the radiator 110 may correspond to a length of the arc. For example, the length of the radiator 110 may be calculated by Equation 1 below.

$$length of radiator = ( R - SD ) * θ \qquad [ Equation 1 ]$$

In Equation 1, R represents a radius of the curved circumference of the antenna dielectric layer 100. SD represents a separation distance of the radiator 110 from the curved circumference of the antenna dielectric layer 100. θ represents an intersection angle between the first virtual straight line VL1 and the second virtual straight line VL2.

In some embodiments, the intersection angle θ may be 90° or less. In an embodiment, the intersection angle θ may be in a range from 10° to 80°, from 15° to 70°, or from 30° to 70°.

A length ratio of the radiator 110 relative to the curved circumference of the antenna dielectric layer 100 may be adjusted to an appropriate range in the intersection angle range. For example, a sufficient antenna gain may be achieved while suppressing radiation cancellation according to the curved shape of the radiator 110.

According to embodiments of the present invention, the radiator 110 may include a mesh portion 115. In some embodiments, the radiator 110 may further include a solid portion 112.

The solid portion 112 may include the above-described metal or alloy, and may refer to one continuous layer without an opening. The mesh portion 115 may include openings formed by conductive lines crossing each other as will be described later.

The solid portion 112 may be adjacent to the curved circumference of the antenna dielectric layer 100, and the mesh portion 115 may be closer to an inner region of the top surface of the antenna dielectric layer 100 than the solid portion 112. The separation distance SD in Equation 1 may represent a separation distance of the solid portion 112 from the curved circumference of the antenna dielectric layer 100.

In example embodiments, the solid portion 112 and the mesh portion 115 have substantially the same curvature and may extend together along the curved circumference of the antenna dielectric layer 100.

The solid portion 112 and the mesh portion 115 may be provided as a single member substantially integrally connected. The pad portion 120 may be integrally connected to the solid portion 112.

According to the above-described embodiments, transparency of the radiator 110 may be increased by the mesh portion 115, and interference of image properties and electrical properties implemented in the electronic device to which the antenna device is applied may be reduced by the mesh portion 115. Further, the solid portion 112 may be disposed around the outer periphery of the antenna dielectric layer 100 to increase a feeding efficiency to the radiator 110 and achieve a sufficient antenna gain.

In some embodiments, boundaries between end portions of the solid portion 112 and the mesh portion 115 may be positioned substantially on the same line. Accordingly, a radiation split of the antenna device may be prevented, and an antenna gain at a desired target resonance frequency may be sufficiently achieved.

In some embodiments, ends of the solid portion 112 and the mesh portion 115 at the other end portion TE of the radiator 110 may not coincide with each other. For example, an extension length of the solid portion 112 may be greater than an extension length of the mesh portion 115, and may further extend from an end of the mesh portion 115 along the curved circumference. In this case, a dual resonance frequency may be substantially implemented from the radiator 110.

In example embodiments, the resonance frequency band of the above-described antenna element AE may cover LTE and WIFI bands. In some embodiments, the resonance frequency band of the antenna element AE may be in a range from 0.1 GHz to 10 GHz, or from 1 GHz to 10 GHz.

FIG. 5 is a schematic plan view illustrating an antenna device according to embodiments. FIG. 6 is a schematic cross-sectional view illustrating an antenna device according to embodiments. For convenience of illustration and description, illustration of the antenna dielectric layer 100 is omitted in FIG. 5. Additionally, the antenna circuit board 150 is illustrated in a state before being bent.

Referring to FIGS. 5 and 6, the antenna device may include the antenna element AE and the above-described antenna circuit board 150 electrically connected to the radiator 110 of the antenna element AE. The antenna element AE including the above-described antenna dielectric layer 100 and the radiator 110 (including the pad part 120) is provided, and the antenna circuit board 150 may be coupled to the antenna element AE. Accordingly, the antenna device in the form of a module or a package may be provided.

The radiator 110 may include a solid metal pattern having an arc shape of a circular sector. In some embodiments, as described with reference to FIG. 4, the radiator 110 may include the solid portion 112 and the mesh portion 115.

The antenna circuit board 150 may include a core layer 160 and a signal wiring 170 formed on one surface of the core layer 160. The core layer 160 may include a flexible resin such as a polyimide resin, a modified polyimide (MPI), an epoxy resin, a polyester, a cycloolefin polymer (COP), a liquid crystal polymer (LCP), or the like. In a preferable embodiment, the core layer 160 may include the polyimide resin or the MPI.

In example embodiments, the antenna circuit board 150 may be a flexible printed circuit board (FPCB) including the above-described flexible resin.

One end portion of the signal wiring 170 may be electrically connected to the pad portion 120. Accordingly, feeding and signal transfer may be performed to the radiator 110 through the signal wiring 170.

The other end portion of the signal wiring 170 may be connected to the first antenna connection structure 190. The first antenna connection structure 190 may be mounted on a surface of the core layer 160 by, e.g., a surface mounting technology (SMT).

The first antenna connection structure 190 may include an insulator 192 and an external connection conductor 195 coupled to the insulator 192.

The one end portion of the signal wiring 170 may be electrically connected to the pad portion 120 of the antenna element AE through a conductive intermediate structure such as a contact 175 or an anisotropic conductive film 140.

In an embodiment, as illustrated in FIG. 5, the one end portion of the signal wiring 170 may be electrically connected to the pad portion 120 of the antenna element AE through the contact 175 penetrating the core layer 160. In this case, the signal wiring 170 and the first antenna connection structure 190 may be disposed together on an outer surface of the core layer 160.

In an embodiment, as illustrated in FIG. 6, the one end portion of the signal wiring 170 may be electrically connected to the pad portion 120 of the antenna element AE through the anisotropic conductive film 140.

For example, the one end portion of the signal wiring 170 and the pad portion 120 may be heated and compressed with the anisotropic conductive film 140 interposed therebetween. Accordingly, an electrical connection between the signal wiring 170 and the pad portion 120 may be implemented.

In this case, the signal wiring 170 may be disposed on then inner surface of the core layer 160, and the first connector (the first antenna connection structure 190) may be disposed on the outer surface of the core layer 160. The first connector 190 may include a signal pin 197 penetrating the core layer 160. The first connector 190 may be in contact with or electrically connected to the signal wiring 170 through the signal pin 197. The signal pin 197 may be connected to an external connection conductor 195 in the insulator 192.

The inner surface of the core layer 160 may refer to a surface of the circuit board 150 or the core layer 160 adjacent to the antenna element AE. The outer surface of the core layer 160 may refer to a surface opposing the inner surface. Based on the cross-section of FIG. 6, the outer surface and the inner surface of the core layer 160 may correspond to an upper surface and a lower surface of the core layer 160, respectively.

In some embodiments, the antenna circuit board 150 may further include a co-planar ground 180. The co-planar ground 180 may include a portion disposed at the same level or on the same surface as that of the signal wiring 170 and extending to be substantially parallel to the signal wiring 170.

As illustrated in FIG. 5, the co-planar ground 180 may include a first portion 180a and a second portion 180b facing each other with the signal wiring 170 interposed therebetween. The first portion 180a and the second portion 180b may be physically separated from the signal wiring 170, and may be substantially parallel to the signal wiring 170.

In some embodiments, the co-planar ground 180 may further include a connection portion 180c connecting end portions of the first portion 180a and the second portion 180b.

In some embodiments, the antenna circuit board 150 may further include a vertical ground 185 facing the signal wiring 170 with the core layer 160 interposed therebetween. When the signal wiring 170 is disposed on the outer surface of the core layer 160, the vertical ground 185 may be disposed on the inner surface of the core layer 160. When the signal wiring 170 is disposed on the inner surface of the core layer 160, the vertical ground 185 may be disposed on the outer surface of the core layer 160.

Noises around the signal wiring 170 may be blocked through the co-planar ground 180, and an electric field concentration to the antenna element AE may be promoted. Noises directed to the antenna circuit board 150 from the electronic device or an external environment may be additionally blocked through the vertical ground 185, and the electric field concentration may be further increased.

As described with reference to FIG. 2, the antenna circuit board 150 may be bent by the first and second bent portions BP1 and BP2, so that the second antenna connection structure 230 of the rear board 200 may be coupled to the first antenna connection structure 190.

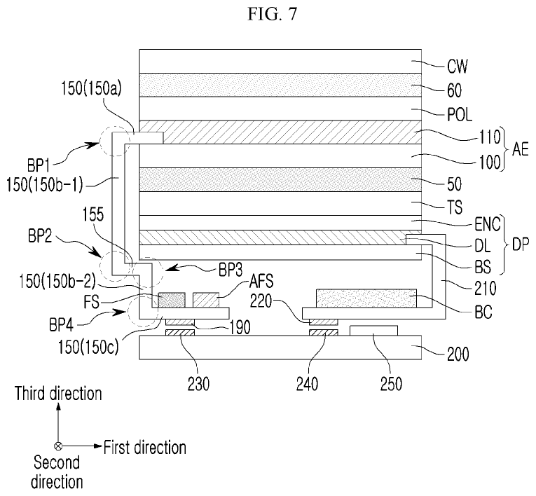

FIG. 7 is a schematic cross-sectional view illustrating an electronic device according to embodiments. Detailed descriptions on elements and structures substantially the same as or similar to those described with reference to FIGS. 1 and 2 are omitted.

Referring to FIG. 7, the antenna circuit board 150 may include first to fourth bent portions BP1, BP2, BP3 and BP4. In example embodiments, the antenna circuit board 150 may be further bent using a bottom edge of the display panel DP or the base substrate BS to generate the second bent portion BP2. Accordingly, the antenna circuit board 150 may include a first vertical extension portion 150b-1 between the first bent portion BP1 and the second bent portion BP2.

The antenna circuit board 150 may be vertically bent under the display panel DP or the base substrate BS to form the third bent portion BP3. Accordingly, the antenna circuit board 150 may include a second vertical extension portion 150b-2 between the third bent portion BP3 and the fourth bent portion BP4.

A portion of the antenna circuit board 150 between the first vertical extension portion 150b-1 and the second vertical extension portion 150b-2 may be defined as an intermediate horizontal extension portion 155.

The second vertical extension portion 150b-2 may be vertically bent again using the forming structure FS to generate the second horizontal extension portion 150c.

As described above, the vertical extension portion 150b may be divided into the first and second vertical extension portions 150b-1 and 150b-2, so that the vertical extension or the vertical bent shape may be stably maintained while preventing the vertical extension portion 150b from being deformed into a curved shape.

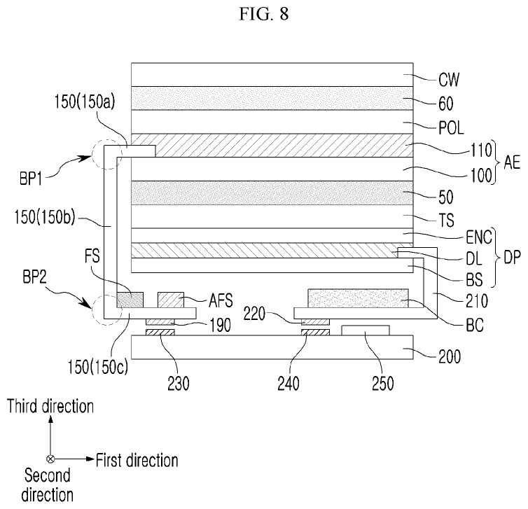

FIG. 8 is a schematic cross-sectional view illustrating an electronic device according to embodiments. Detailed descriptions on elements and structures substantially the same as or similar to those described with reference to FIGS. 1 and 2 are omitted.

Referring to FIG. 8, the forming structure FS may be in contact with an inner surface or an inner wall of the vertical extension portion 150b on the second horizontal extension portion 150c of the antenna circuit board 150. Accordingly, a vertical extension shape of the vertical extension portion 150b may be supported, and the vertical extension portion 150b may be prevented from being deformed into a curved shape.

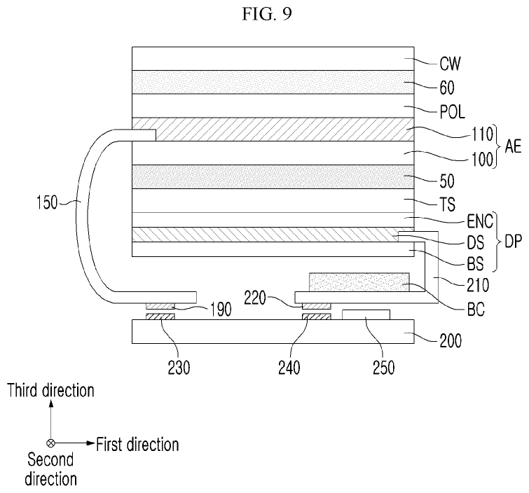

FIG. 9 is a cross-sectional view illustrating an electronic device according to Comparative Example.

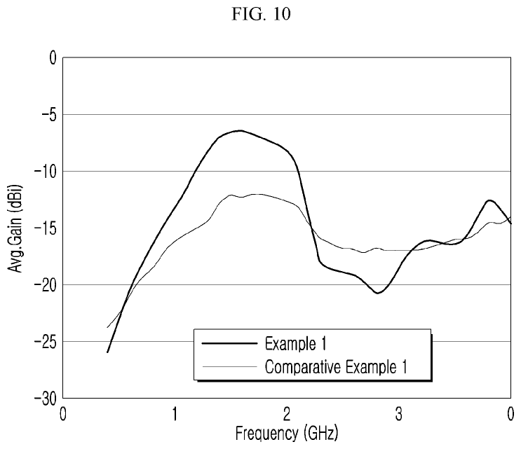

FIG. 10 is a graph showing a gain according to a frequency of the electronic devices according to Example and Comparative Example.

In Example, a circular COP antenna dielectric layer 100 having a diameter (a curved circumferential length of about 103 mm) of 32.8 mm was prepared. An antenna element AE of Example was obtained by forming the radiator 110 in the form of FIG. 4 along the curved circumference of the antenna dielectric layer 100. A length of the radiator 110 was adjusted to 17.08 mm and a line width of the radiator 110 was adjusted to 500 μm.

The antenna element AE was stacked on a product sample of the display panel DP, one end portion of a flexible printed circuit board (FPCB) as the antenna circuit board 150 was bonded to the pad portion 120 of the antenna element AE, and the antenna circuit board 150 was vertically bent along a sidewall of the display panel DP.

After vertically bending the other end portion of the antenna circuit board 150 using the forming structure FS formed of an elastic resin, the first antenna connection structure 190 mounted on the other end portion of the antenna circuit board 150 was combined with the second antenna connection structure 230 mounted on the rear board 200 as illustrated in FIG. 2.

In Comparative Example, as illustrated in FIG. 9, the forming structure FS was omitted, and the antenna circuit board 150 was extended with a curvature due to a flexibility of the antenna circuit board 150.

An average gain of antenna elements included in the electronic devices of Example and Comparative Example was measured in a radiation chamber.

Referring to FIG. 10, an average gain of −6.4 dBi was measured in Example and −12.3 dBi was measured in Comparative Example at a resonance frequency of 1.6 GHz. In Example, a stable vertical extension shape of the antenna circuit board 150 was maintained by the forming structure, so that a signal loss was reduced.

In Comparative Example, a signal loss was caused by the curvature of the antenna circuit board 150.

What is claimed is:

1. An electronic device comprising:
a display panel;
an antenna element stacked on the display panel;
a rear board disposed under the display panel;
an antenna circuit board comprising one end portion connected to the antenna element, the other end portion connected to the rear board, and a vertical extension portion between the one end portion and the other end portion; and
a forming structure disposed on the other end portion of the antenna circuit board to be adjacent to an inner surface of the vertical extension portion.

2. The electronic device of claim 1, wherein the forming structure comprises an elastic resin material.

3. The electronic device of claim 2, further comprising an auxiliary forming structure disposed on the other end portion of the antenna circuit board.

4. The electronic device of claim 3, wherein the auxiliary forming structure is spaced apart from the vertical extension portion of the antenna circuit board with the forming structure interposed therebetween.

5. The electronic device of claim 3, wherein the auxiliary forming structure is a sensor element including a conductor.

6. The electronic device of claim 1, wherein the antenna circuit board has a first bent portion formed between the one end portion and the vertical extension portion, and a second bent portion formed between the other end portion and the vertical extension portion.

7. The electronic device of claim 6, wherein a bent angle of each of the first bent portion and the second bent portion is within a range of 80° to 100°.

8. The electronic device of claim 6, wherein the first bent portion and the second bent portion do not include a curved surface.

9. The electronic device of claim 6, wherein the one end portion of the antenna circuit board includes a first horizontal extension portion, and the other end portion of the antenna circuit board includes a second horizontal extension portion.

10. The electronic device of claim 6, wherein the antenna circuit board has a third bent portion under the display panel and a fourth bent portion adjacent to the forming structure, and
the vertical extension portion includes a first vertical extension portion between the first bent portion and the second bent portion, and a second vertical extension portion between the third bent portion and the fourth bent portion.

11. The electronic device of claim 1, wherein the forming structure contacts an inner surface of the vertical extension portion of the antenna circuit board.

12. The electronic device of claim 1, further comprising:
a first antenna connection structure mounted on the other end portion of the antenna circuit board; and
a second antenna connection structure mounted on the rear board and coupled to the first antenna connection structure.

13. The electronic device of claim 12, wherein the forming structure is disposed on an inner surface of the other end portion of the antenna circuit board, and the first antenna connection structure is mounted on an outer surface opposing the inner surface of the other end portion of the antenna circuit board.

14. The electronic device of claim 12, wherein the first antenna connection structure and the second antenna connection structure include a connector, a pogo pin, or a c-clip.

15. The electronic device of claim 1, wherein the antenna element comprises:
an antenna dielectric layer having a curved circumference; and
a radiator electrically connected to the antenna circuit board, the radiator extending along the curved circumference of the antenna dielectric layer and having a curved shape.

16. The electronic device of claim 15, wherein the radiator comprises a mesh portion.

17. The electronic device of claim 16, wherein the radiator further comprises a solid portion.

18. The electronic device of claim 17, wherein the solid portion and the mesh portion are integrally connected and have the same curvature.

19. The electronic device of claim 1, wherein the electronic device is provided as a smartwatch.
